(19) United States
(12) Patent Application Publication
(10) Pub. No.: US 2026/0293558 A1
(43) Pub. Date: Sep. 24, 2026

(54) SEMICONDUCTOR DEVICE MANUFACTURING METHOD AND SEMICONDUCTOR DEVICE

(71) Applicant: RAPIDUS CORPORATION, Tokyo (JP)

(72) Inventor: Takuya Masunaga, Albany, NY (US)

(21) Appl. No.: 19/433,390

(22) Filed: Dec. 26, 2025

Related U.S. Application Data
(60) Provisional application No. 63/750,491, filed on Jan. 28, 2025.

(30) Foreign Application Priority Data
Jul. 23, 2025 (JP) 2025-123435

(51) Int. Cl. H10P 50/00; H10P 76/20

(52) U.S. Cl. CPC H10P 50/694; H10P 76/2041

(57) ABSTRACT

A semiconductor device manufacturing method according to the present embodiment includes: a step of applying a photoresist onto a first pattern to be a patterning layer formed by patterning; a step of exposing the photoresist using a mask in which a second pattern is supplementarily added to the first pattern; a step of developing the exposed photoresist in order to form the second pattern and a resist residue; and a step of etching the patterning layer using the dried photoresist. In the etching step, the resist residue of the second pattern is also etched and reduced such that a portion of the patterning layer patterned on the basis of the resist residue of the second pattern does not affect electrical characteristics of the patterning layer patterned on the basis of the first pattern.

### BACKGROUND OF THE INVENTION

### 1. Technical Field

Disclosure of the present specification and the drawings relates to a semiconductor device manufacturing method and a semiconductor device.

### 2. Description of the Related Art

In a semiconductor device manufacturing process, a step of forming a photoresist on a patterning layer such as a wiring layer or an insulating layer and patterning the patterning layer into a desired pattern is repeated many times. After the photoresist is applied and formed, the photoresist is exposed using a mask of a desired pattern, and the exposed photoresist is developed and dried to obtain a photoresist of a desired pattern. Then, the patterning layer is etched using the photoresist of the desired pattern as a mask. As a result, the patterning layer is etched into a desired pattern.

However, as miniaturization of a semiconductor device progresses, a pattern of a photoresist is also miniaturized, and there is a problem that the pattern of the developed and dried photoresist collapses. This is considered to be because water used for developing the photoresist remains between the patterns in a process of drying due to a capillary phenomenon, and the patterns of the photoresist collapse due to surface tension of water.

Patent Literature 1: JP H10-319598 A

### SUMMARY OF THE INVENTION

Disclosure of the present specification and the drawings has been made in order to solve the above problems, and an object thereof is to avoid collapse of a pattern of a photoresist in a process of patterning a patterning layer into a desired pattern.

A semiconductor device manufacturing method according to the present embodiment includes: a step of applying a photoresist onto a first pattern to be a patterning layer formed by patterning; a step of exposing the photoresist using a mask in which a second pattern is supplementarily added to the first pattern; a step of developing the exposed photoresist in order to form the second pattern and a resist residue; and a step of etching the patterning layer using the dried photoresist. In the etching step, the resist residue of the second pattern is also etched and reduced such that a portion of the patterning layer patterned on the basis of the resist residue of the second pattern does not affect electrical characteristics of the patterning layer patterned on

### BRIEF DESCRIPTION OF THE DRAWINGS

FIG. 1A is a plan view (part 1) of a semiconductor substrate for explaining a semiconductor device manufacturing process according to a first embodiment;

FIG. 1B is a cross-sectional view (part 1) of the semiconductor substrate taken along line B-B for explaining the semiconductor device manufacturing process according to the first embodiment;

FIG. 2A is a plan view (part 2) of the semiconductor substrate for explaining the semiconductor device manufacturing process according to the first embodiment;

FIG. 2B is a cross-sectional view (part 2) of the semiconductor substrate taken along line B-B for explaining the semiconductor device manufacturing process according to the first embodiment;

FIG. 3A is a plan view (part 3) of the semiconductor substrate for explaining the semiconductor device manufacturing process according to the first embodiment;

FIG. 3B is a cross-sectional view (part 3) of the semiconductor substrate taken along line B-B for explaining the semiconductor device manufacturing process according to the first embodiment;

FIG. 4A is a plan view (part 4) of the semiconductor substrate for explaining the semiconductor device manufacturing process according to the first embodiment;

FIG. 4B is a cross-sectional view (part 4) of the semiconductor substrate taken along line B-B for explaining the semiconductor device manufacturing process according to the first embodiment;

FIG. 4C is a cross-sectional view (part 4) of the semiconductor substrate taken along line C-C for explaining the semiconductor device manufacturing process according to the first embodiment;

FIG. 5A is a plan view (part 5) of the semiconductor substrate for explaining the semiconductor device manufacturing process according to the first embodiment;

FIG. 5B is a cross-sectional view (part 5) of the semiconductor substrate taken along line B-B for explaining the semiconductor device manufacturing process according to the first embodiment;

FIG. 5C is a cross-sectional view (part 5) of the semiconductor substrate taken along line C-C for explaining the semiconductor device manufacturing process according to the first embodiment;

FIG. 5D is a cross-sectional view (part 5) of the semiconductor substrate taken along line D-D for explaining an etching step on the semiconductor substrate in the semiconductor device manufacturing process according to the first embodiment;

FIG. 6A is a plan view (part 6) of the semiconductor substrate for explaining the semiconductor device manufacturing process according to the first embodiment;

FIG. 6B is a cross-sectional view (part 6) of the semiconductor substrate taken along line B-B for explaining the semiconductor device manufacturing process according to the first embodiment;

FIG. 6C is a cross-sectional view (part 6) of the semiconductor substrate taken along line C-C for explaining the semiconductor device manufacturing process according to the first embodiment;

FIG. 7 is a perspective view illustrating an example of a photoresist that has been subjected to a development step and a drying step in the first embodiment;

FIG. 8A is a plan view (part 2) of a semiconductor substrate for explaining a semiconductor device manufacturing process according to a second embodiment, following FIG. 1A

FIG. 8B is a cross-sectional view (part 2) of the semiconductor substrate taken along line B-B for explaining the semiconductor device manufacturing process according to the second embodiment, following FIG. 1B;

FIG. 9A is a plan view (part 3) of the semiconductor substrate for explaining the semiconductor device manufacturing process according to the second embodiment;

FIG. 9B is a cross-sectional view (part 3) of the semiconductor substrate taken along line B-B for explaining the semiconductor device manufacturing process according to the second embodiment;

FIG. 10A is a plan view (part 4) of the semiconductor substrate for explaining the semiconductor device manufacturing process according to the second embodiment;

FIG. 10B is a cross-sectional view (part 4) of the semiconductor substrate taken along line B-B for explaining the semiconductor device manufacturing process according to the second embodiment;

FIG. 10C is a cross-sectional view (part 4) of the semiconductor substrate taken along line C-C for explaining the semiconductor device manufacturing process according to the second embodiment;

FIG. 11A is a plan view (part 5) of the semiconductor substrate for explaining the semiconductor device manufacturing process according to the second embodiment;

FIG. 11B is a cross-sectional view (part 5) of the semiconductor substrate taken along line B-B for explaining the semiconductor device manufacturing process according to the second embodiment;

FIG. 11C is a cross-sectional view (part 5) of the semiconductor substrate taken along line C-C for explaining the semiconductor device manufacturing process according to the second embodiment;

FIG. 12A is a plan view (part 6) of the semiconductor substrate for explaining the semiconductor device manufacturing process according to the second embodiment;

FIG. 12B is a cross-sectional view (part 6) of the semiconductor substrate taken along line B-B for explaining the semiconductor device manufacturing process according to the second embodiment;

FIG. 12C is a cross-sectional view (part 6) of the semiconductor substrate taken along line C-C for explaining the semiconductor device manufacturing process according to the second embodiment;

FIG. 13A is a plan view (part 2) of a semiconductor substrate for explaining a semiconductor device manufacturing process according to a third embodiment, following FIG. 1A;

FIG. 13B is a cross-sectional view (part 2) of the semiconductor substrate taken along line B-B for explaining the semiconductor device manufacturing process according to the third embodiment, following FIG. 1B;

FIG. 14A is a plan view (part 3) of the semiconductor substrate for explaining the semiconductor device manufacturing process according to the third embodiment;

FIG. 14B is a cross-sectional view (part 3) of the semiconductor substrate taken along line B-B for explaining the semiconductor device manufacturing process according to the third embodiment;

FIG. 15A is a plan view (part 4) of the semiconductor substrate for explaining the semiconductor device manufacturing process according to the third embodiment;

FIG. 15B is a cross-sectional view (part 4) of the semiconductor substrate taken along line B-B for explaining the semiconductor device manufacturing process according to the third embodiment;

FIG. 15C is a cross-sectional view (part 4) of the semiconductor substrate taken along line C-C for explaining the semiconductor device manufacturing process according to the third embodiment;

FIG. 16A is a plan view (part 5) of the semiconductor substrate for explaining the semiconductor device manufacturing process according to the third embodiment;

FIG. 16B is a cross-sectional view (part 5) of the semiconductor substrate taken along line B-B for explaining the semiconductor device manufacturing process according to the third embodiment;

FIG. 16C is a cross-sectional view (part 5) of the semiconductor substrate taken along line C-C for explaining the semiconductor device manufacturing process according to the third embodiment;

FIG. 17A is a plan view (part 6) of the semiconductor substrate for explaining the semiconductor device manufacturing process according to the third embodiment;

FIG. 17B is a cross-sectional view (part 6) of the semiconductor substrate taken along line B-B for explaining the semiconductor device manufacturing process according to the third embodiment;

FIG. 17C is a cross-sectional view (part 6) of the semiconductor substrate taken along line C-C for explaining the semiconductor device manufacturing process according to the third embodiment; and

FIG. 18 is a plan view of a semiconductor substrate for explaining a modification of the third embodiment, corresponding to FIG. 13A.

### DETAILED DESCRIPTION

Hereinafter, embodiments of a semiconductor device manufacturing method and a semiconductor device will be described with reference to the drawings. Note that, in the following description, components having substantially same functions and configurations are denoted by the same reference numerals, and redundant description will be made only when necessary.

### First Embodiment

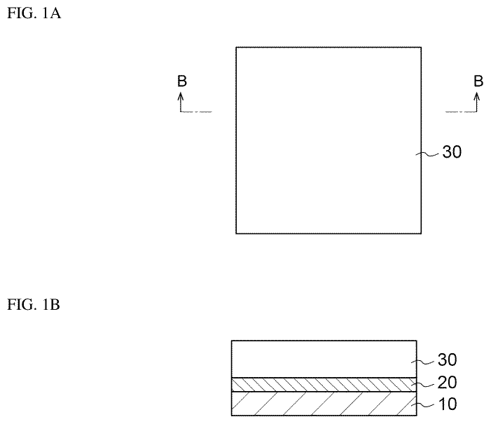

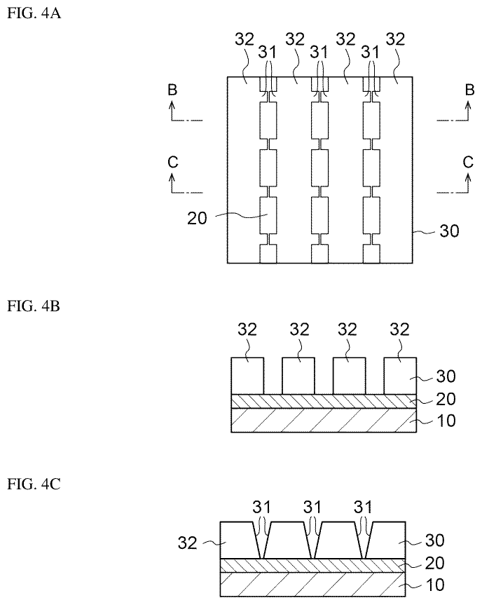

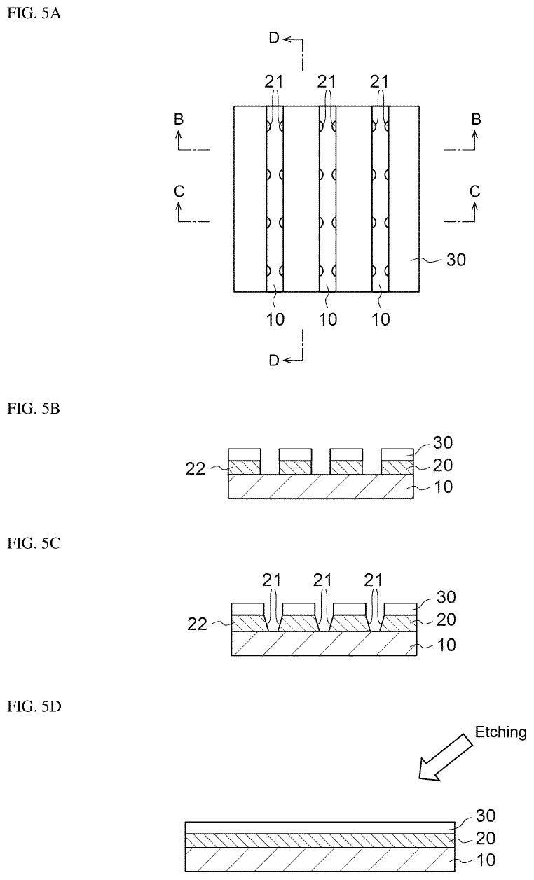

FIGS. 1A and 1B to 6A to 6C are views for explaining a semiconductor device manufacturing process according to a first embodiment. More specifically, FIGS. 1A to 6A are plan views of a semiconductor device for explaining the semiconductor device manufacturing process according to the present embodiment. FIGS. 1B to 6B are cross-sectional views of FIGS. 1A to 6A taken along line B-B, respectively. FIGS. 4C to 6C are cross-sectional views of FIGS. 4A to 6A taken along line C-C, respectively. FIG. 5D is a cross-sectional view of FIG. 5A taken along line D-D.

First, as illustrated in FIGS. 1A and 1B, a patterning layer 20 is formed on a semiconductor substrate 10. The semiconductor substrate 10 is, for example, a disk-shaped substrate called a wafer, and is made of a material such as Si, SiC, GaAs, or GaN. The patterning layer 20 is a generic term for a layer to be patterned into a desired pattern in the present embodiment. The patterning layer 20 includes, for example, a conductive layer, a semiconductor layer, an insulating layer, or a combination thereof.

In the example of FIGS. 1A and 1B, the patterning layer 20 is formed on the semiconductor substrate 10, but this merely illustrates a state for convenience for simplifying the description of the present embodiment. Actually, in the semiconductor device manufacturing process, since a semiconductor device is formed by stacking a plurality of layers, the patterning layer 20 is formed not on the semiconductor substrate 10 but on various other layers such as a conductive layer, a semiconductor layer, an insulating layer, and a combination thereof.

In the present embodiment, the patterning layer 20 is a layer to be patterned into a first pattern in design. That is, in designing a semiconductor device, a desired pattern of the patterning layer 20 is the first pattern.

Subsequently, a photoresist 30 is applied onto the patterning layer 20 to be formed thereon. The photoresist 30 is made of, for example, a mixed material such as a photosensitive resin and a solvent. For example, a solution made of this mixed material is applied onto the patterning layer 20 by spin coating, whereby the photoresist 30 is formed on the patterning layer 20. In the present embodiment, for example, the photoresist 30 having a uniform film thickness is formed by rotating a disk-shaped wafer at a high speed while dropping the solution on the patterning layer 20 by a spin coater.

This photoresist 30 includes a positive photoresist in which a portion irradiated with light is chemically changed and easily dissolved in a developer, and a negative photoresist in which a portion irradiated with light is chemically changed and hardly dissolved in a developer. The present embodiment can be applied to both the positive photoresist and the negative photoresist. In the following description, the present embodiment will be described by taking the positive photoresist 30 as an example.

Subsequently, the photoresist 30 on the patterning layer 20 is prebaked by heating. By performing this prebaking, a solvent or the like remaining in the photoresist 30 is volatilized and removed. As a result, the photoresist 30 is cured to be stabilized, uniformity of the film thickness of the photoresist 30 is ensured, and adhesion between the patterning layer 20 and the photoresist 30 is improved.

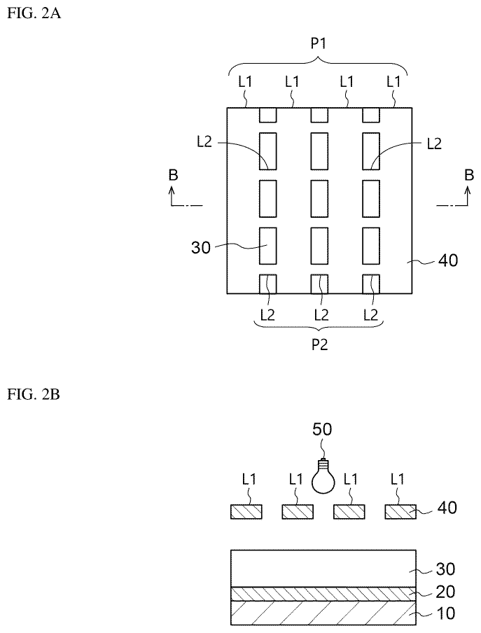

Next, as illustrated in FIGS. 2A and 2B, the photoresist 30 is exposed using an exposure mask 40. In the present embodiment, an exposure light source 50 of an exposure apparatus irradiates the photoresist 30 with extreme ultraviolet (EUV). More specifically, in the present embodiment, the exposure light source 50 irradiates the photoresist 30 with light having a wavelength of, for example, 13.5 nm for exposure.

The exposure mask 40 is a mask having a pattern in which a second pattern P2 is supplementarily added to the first pattern P1 described above. In the example of FIGS. 2A and 2B, four parallel mask lines L1 having a constant line width are formed as the first pattern P1. This first pattern P1 is a design pattern of the semiconductor device.

The second pattern P2 is supplementarily added to this first pattern P1. In the example of FIGS. 2A and 2B, a plurality of auxiliary lines L2 are added between the parallel mask lines L1 of the first pattern P1. In this example, the plurality of auxiliary lines L2 are added between the parallel mask lines L1 at regular intervals. In other words, in the second pattern P2, the plurality of auxiliary lines L2 are continuously arranged in a certain direction and added to the first pattern P1. In the present embodiment, as described above, the photoresist 30 is exposed using the mask 40 in which the second pattern P2 is supplementarily added to the first pattern P1 which is a design pattern.

In a subsequent development step, after the photoresist 30 is developed on the basis of the first pattern P1, the photoresist 30 remains and becomes a remaining resist. This remaining resist matches the first pattern P1 which is a design pattern, and the second pattern P2 is added to the first pattern P1 such that each of the auxiliary lines L2 is in contact with this remaining resist. In the example of FIGS. 2A and 2B, as a result, when the first pattern P1 and the second pattern P2 are combined, the mask 40 is formed into a ladder-shaped pattern.

In the present embodiment, the line width of the parallel mask lines L1 in the first pattern P1 is between one time and two times the wavelength of the exposure light source 50. That is, the line width formed in the patterning layer 20 in the first pattern Pl is between one time and two times the wavelength of the exposure light source 50. As described above, in the present embodiment, since the exposure light source 50 emits light having a wavelength of, for example, 13.5 nm, the line width corresponding to the mask line L1 formed in the patterning layer 20 is between 13.5 nm and 27 nm. In general, with the line width at this level, a problem that the developed and dried photoresist 30 collapses easily occurs.

In addition, in the present embodiment, for example, the photoresist 30 is exposed using a lens having a numerical aperture of 0.55 or more. This is so-called EUV exposure of a High-NA region, which is also a region where collapse of the developed and dried photoresist 30 may become a problem.

Note that the exposure mask 40 illustrated in FIGS. 2A and 2B is merely a partial example of the mask 40. That is, as a partial example of the exposure mask 40, the parallel mask lines L1 and the plurality of auxiliary lines L2 are illustrated, and actually, another exposure line such as another wiring is present in the exposure mask 40.

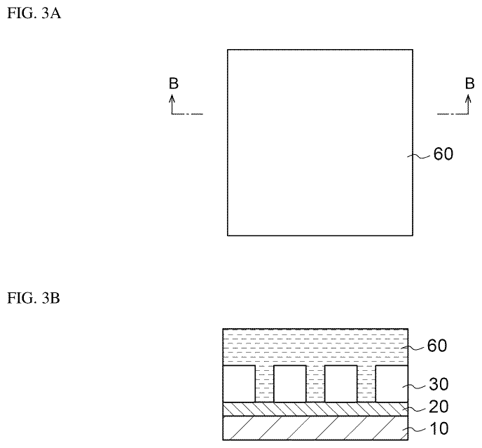

Next, as illustrated in FIGS. 3A and 3B, the exposed photoresist 30 is developed. Specifically, the photoresist 30 is immersed in a developer, and a part of the photoresist 30 is selectively removed by utilizing a change in solubility due to exposure. In the present embodiment, since the positive photoresist 30 is used, an exposed portion is dissolved in the developer and removed. Therefore, a pattern of the remaining photoresist 30 matches a pattern of the mask 40 including the first pattern P1 and the second pattern P2. After the developer used in this exposure step is discarded, the semiconductor device is cleaned using water such as pure water, and the developer is removed so as not to remain.

Next, as illustrated in FIGS. 4A to 4C, the developed photoresist 30 is dried. In this drying step, the photoresist 30 corresponding to the parallel mask lines L1 of the first pattern P1 in the mask 40 remains as it is, but the photoresist 30 corresponding to the auxiliary lines L2 of the second pattern P2 in the mask 40 is partially dissolved and remains as a resist residue 31. That is, the portion of the auxiliary lines L2 of the second pattern P2 is smaller than the parallel mask lines L1 of the first pattern P1, and therefore is partially dissolved in the development step, and remains as the resist residue 31 after the drying step. In other words, the auxiliary lines L2 of the second pattern P2 are not so large that the auxiliary lines L2 remain as they are after the development step and the drying step, but can be said to be so large that the auxiliary lines L2 of the second pattern P2 remain as the resist residues 31.

In addition, as can be seen from FIG. 4B, in a portion where the auxiliary line L2 of the second pattern P2 is not formed, the photoresist 30 remains in a shape corresponding to the first pattern P1 which is a design pattern, and becomes a remaining resist 32. In the example of FIG. 4B, the remaining resist 32 of the photoresist 30 is formed in a pattern corresponding to the parallel mask lines L1 of the first pattern P1.

On the other hand, as can be seen from FIG. 4C, presence of the resist residue 31 of the second pattern P2 can suppress collapse of the remaining resists 32 of the photoresist 30 corresponding to the parallel mask lines L1 of the first pattern P1. That is, the resist residue 31 serves as a support to prevent the remaining resist 32 of the photoresist 30 corresponding to the design pattern from collapsing. Therefore, it can be said that the size of the resist residue 31 is at least enough to suppress collapse of the photoresist 30 formed in the first pattern P1.

In addition, as can be seen from FIG. 4C, the resist residue 31 has a widened skirt portion in contact with the patterning layer 20, and has stability. By such a shape of the resist residue 31, the remaining resist 32 of the photoresist 30 formed in the first pattern P1 can be stably supported, and collapse of the remaining resist 32 is suppressed. That is, a phenomenon that water used in the development step remains between the remaining resists 32 of the photoresist 30 due to a capillary phenomenon and the remaining resists 32 of the photoresist 30 collapse due to surface tension of water is avoided by support of the remaining resists 32 by the resist residue 31. On the other hand, the resist residues 31 are separated from each other, and there is no portion where the resist residues 31 are connected to each other. Therefore, even if the patterning layer 20 is etched using the photoresist 30 in which the resist residue 31 is present, electrical characteristics of the patterning layer 20 patterned by etching are not adversely affected.

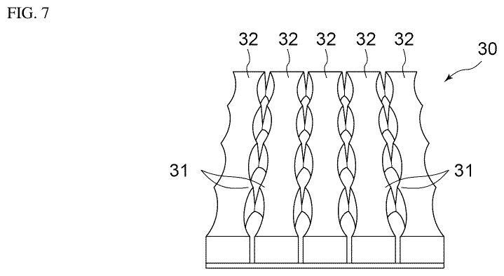

FIG. 7 is a perspective view illustrating an example of the photoresist 30 actually developed and dried. As illustrated in FIG. 7, in the photoresist 30 of the present embodiment, the resist residues 31 corresponding to the second pattern P2 are arranged at regular intervals in a direction intersecting with a longitudinal direction of the first pattern P1. The height of the resist residue 31 at this time largely depends on a material of the photoresist 30, development conditions, drying conditions, and the like. For example, in the example of FIG. 7, when the height of the resist residue 31 is 1, the height of the remaining resist 32 of the photoresist 30 corresponding to the first pattern P1 is 10.

When the patterning layer 20 is etched in the above-described state of FIGS. 4A to 4C, the semiconductor device becomes the state of FIGS. 5A to 5D.

As can be seen from FIGS. 5A to 5C, the patterning layer 20 is etched and patterned on the basis of the photoresist 30 including the first pattern P1 and the resist residue 31. By this etching, the film thickness of the photoresist 30 of the first pattern P1 is reduced, and the resist residue 31 of the second pattern P2 is also etched and reduced. By reduction of the resist residue 31, an auxiliary additional portion 21 of the patterning layer 20 patterned on the basis of the resist residue 31 can be prevented from affecting electrical characteristics of a first member 22 of the patterning layer 20 patterned on the basis of the first pattern P1.

That is, in the present embodiment, by this etching, the auxiliary additional portion 21 is patterned and formed in the patterning layer 20 on the basis of the resist residue 31. However, since the resist residues 31 are sufficiently separated from each other, the auxiliary additional portions 21 are also formed so as to be separated from each other. Therefore, in the patterning layer 20 patterned on the basis of the first pattern P1, a situation in which a portion that should not be connected in design is connected does not occur. In the present embodiment, the first members 22 of the patterning layer 20 corresponding to the parallel mask lines L1 in the first pattern P1 are separated from each other even if the auxiliary additional portion 21 corresponding to the resist residue 31 is present, and as a result, presence of the resist residue 31 does not affect electrical characteristics of the first members 22 of the patterning layer 20 corresponding to the parallel mask lines L1.

As can be seen from FIG. 5D, in the present embodiment, the patterning layer 20 is etched by directional etching. That is, the patterning layer 20 is irradiated with ions from obliquely above to be etched. Such directional etching can be implemented by performing etching by inclining the entire semiconductor substrate 10, or can be implemented by performing etching by inclining ion irradiation while keeping the semiconductor substrate 10 horizontal.

In the present embodiment, the patterning layer 20 is etched by performing directional etching from a direction intersecting with a longitudinal direction of the auxiliary line L2 of the second pattern P2, that is, from a direction along the mask line L1 of the first pattern P1. As a result, the resist residue 31 of the photoresist 30 formed corresponding to the auxiliary line L2 is also etched, and the size thereof is reduced. This is because not only the patterning layer 20 but also the resist residue 31 is etched by irradiating a side wall of the resist residue 31 with ions from obliquely above.

Therefore, by etching the patterning layer 20 by directional etching, the size of the resist residue 31 can be further reduced, and it is possible to more reliably avoid presence of the resist residue 31 from adversely affecting electrical characteristics of the patterning layer 20 patterned on the basis of the first pattern P1. That is, reliability of the manufacturing process can be improved by adopting directional etching.

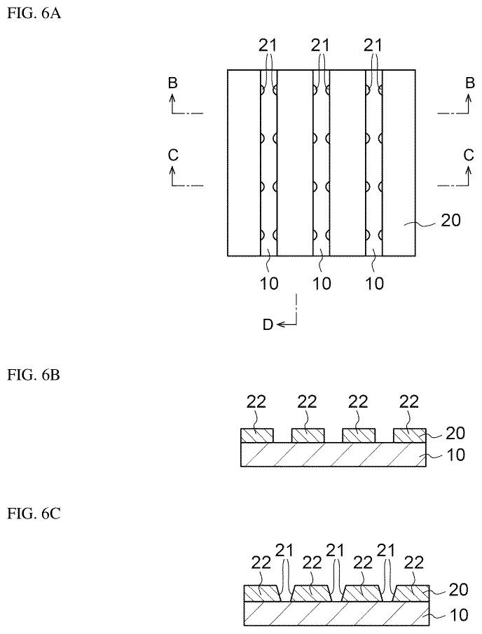

When the photoresist 30 is cleaned and removed from the state of FIGS. 5A to 5D, the semiconductor substrate becomes the state of FIGS. 6A to 6C. In the present embodiment, the photoresist 30 is removed by, for example, ashing or cleaning using a cleaning liquid. As a result, the semiconductor device manufacturing process for patterning the patterning layer 20 in the present embodiment is completed. Then, this semiconductor substrate shifts to a next manufacturing process.

As illustrated in FIGS. 6A to 6C, the patterning layer 20 includes the first member 22 corresponding to the first pattern P1 which is a design pattern, and the auxiliary additional portion 21 added to the first member 22 and formed continuously with the first member 22. This auxiliary additional portion 21 corresponds to a second member in the present embodiment.

As described above, the auxiliary additional portion 21 which is the second member is formed by the resist residue 31 of the photoresist 30 of the second pattern P2 supplementarily added to the first pattern P1. These auxiliary additional portions 21 which are the second members are separated from the first member 22 and from each other. Therefore, the auxiliary additional portion 21 which is the second member does not affect electrical characteristics of the first member 22 formed in the first pattern P1.

As described above, according to the semiconductor device manufacturing method according to the present embodiment, the photoresist 30 is exposed, developed, and dried using the mask 40 having a pattern in which the second pattern P2 is supplementarily added to the first pattern P1. Therefore, in the development step and the drying step, the resist residue 31 corresponding to the second pattern P2 has a structure supporting the remaining resist 32 corresponding to the first pattern P1, and collapse of the remaining resist 32 corresponding to the first pattern P1 can be avoided.

In addition, since the resist residue 31 corresponding to the second pattern P2 is etched in a subsequent etching step and the size thereof is reduced, the auxiliary additional portions 21 of the patterning layer 20 patterned on the basis of the resist residue 31 can be separated from each other, and can also be separated from the patterning layer 20 patterned on the basis of the first pattern P1. Therefore, even if the second pattern P2 is supplementarily added to the first pattern P1, electrical characteristics of the patterning layer 20 patterned based on the first pattern P1 can be prevented from being affected.

Note that, as illustrated in FIGS. 6A to 6C, the auxiliary additional portion 21 generated on the basis of the resist residue 31 remains in the patterning layer 20. For example, when the first pattern Pl is a wiring, the auxiliary additional portion 21 remains in a part of the wiring.

However, since the auxiliary additional portion 21 is not in contact with another wiring, the auxiliary additional portion 21 does not affect electrical characteristics of the wiring.

### Second Embodiment

In the first embodiment described above, the mask 40 used in the exposure step has a ladder-shaped pattern, but the pattern of the mask 40 can be arbitrarily changed. In the following second embodiment, an example will be described in which the mask 40 used in the exposure step is modified into a pattern in which the plurality of auxiliary lines L2 are dispersed. Note that, in the description of the second embodiment, portions different from those of the first embodiment described above will be mainly described.

A semiconductor device manufacturing process according to the second embodiment is the same as that of the first embodiment described above up to FIGS. 1A and 1B. That is, the process is similar to that in the first embodiment described above until the photoresist 30 is formed on the patterning layer 20 and prebaked by heating.

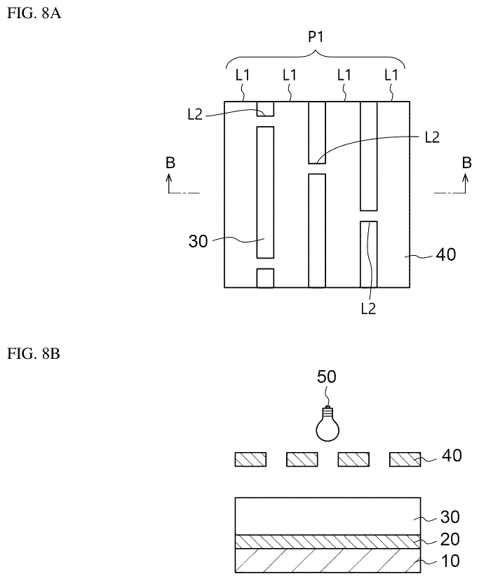

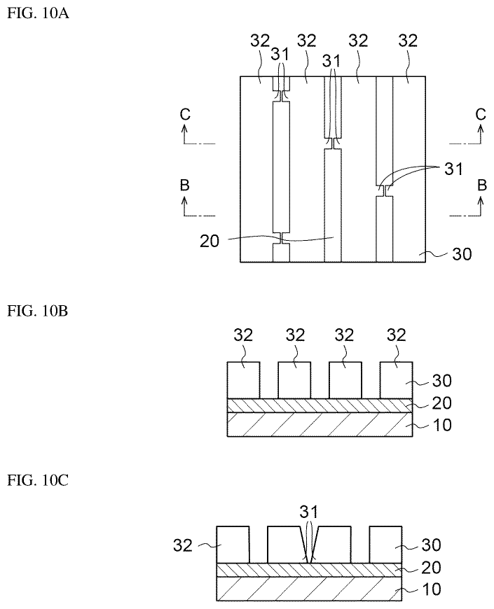

FIGS. 8A to 12A are plan views for explaining the semiconductor device manufacturing process according to the present embodiment, following FIGS. 1A and 1B, and are views corresponding to FIGS. 2A to 6A in the first embodiment described above, respectively. FIGS. 8B to 12B are cross-sectional views of FIGS. 8A to 12A taken along line B-B, respectively. FIGS. 10C to 12C are cross-sectional views of FIGS. 10A to 12A taken along line C-C, respectively.

As illustrated in FIGS. 8A and 8B, the photoresist 30 is exposed using the exposure mask 40 as in the first embodiment described above. Note that a pattern of the exposure mask 40 according to the present embodiment is different from the pattern of the exposure mask 40 of the first embodiment described above. That is, a pattern of the second pattern P2 supplementarily added to the first pattern P1 is different from the pattern of the second pattern P2 of the first embodiment.

Specifically, the plurality of auxiliary lines L2 in the second pattern P2 are discontinuously dispersed and added to the first pattern P1. That is, the plurality of auxiliary lines L2 are discontinuously scattered between the parallel mask lines L1 in the first pattern P1. In this example, the plurality of auxiliary lines L2 are arranged in the first pattern Pl so as not to be arranged in the same line but to be different lines. In the example of FIGS. 8A and 8B, the plurality of auxiliary lines L2 in the second pattern P2 are dispersed in a stepwise arrangement between the parallel mask lines L1.

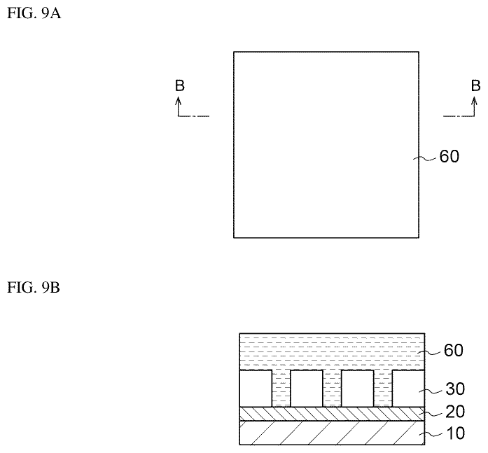

Next, as illustrated in FIGS. 9A and 9B, the exposed photoresist 30 is developed as in the first embodiment described above. This development step is the same as that in the first embodiment described above.

Next, as illustrated in FIGS. 10A to 10C, the developed photoresist 30 is dried as in the first embodiment described above. Through the development step and the drying step, the resist residue 31 corresponding to the second pattern P2 is formed in the photoresist 30. The fact that the resist residue 31 is formed is similar to the first embodiment described above, but since the position of the auxiliary line L2 in the second pattern P2 is different from that of the first embodiment, a position where the resist residue 31 is formed is also different from that of the first embodiment.

As can be seen from the example illustrated in FIG. 10C, a pair of the resist residues 31 is formed between a pair of parallel mask lines L1, but the resist residue 31 is not formed between other parallel mask lines L1 in the same cross section. By forming the resist residues 31 in a discontinuously dispersed manner as described above, the remaining resist 32 of the photoresist 30 corresponding to the first pattern P1 can be supported by the resist residues 31 in a well-balanced manner to suppress collapse of the remaining resist 32. That is, a phenomenon that water used in the development step remains between the remaining resists 32 of the photoresist 30 due to a capillary phenomenon and the remaining resists 32 of the photoresist 30 collapse due to surface tension of water can be avoided by support of the remaining resists 32 by the resist residues 31 from various positions. Therefore, the number of the plurality of auxiliary lines L2 in the second pattern P2 can also be reduced as a whole as compared with that of the first embodiment.

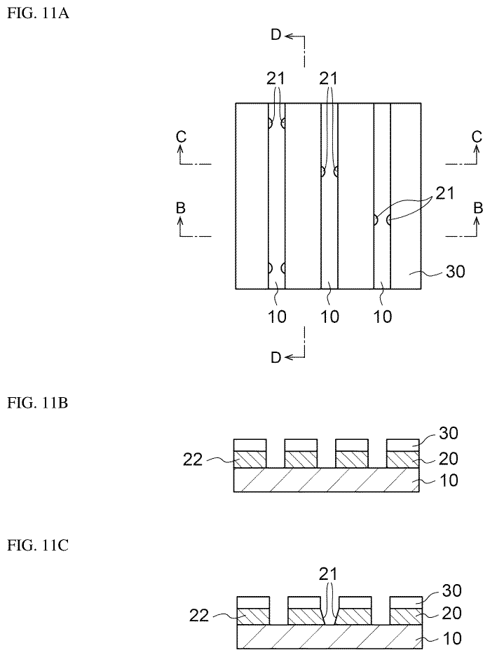

When the patterning layer 20 is etched in the state of FIGS. 10A to 10C, the semiconductor device becomes the state of FIGS. 11A to 11C. In particular, in the present embodiment, the patterning layer 20 is etched by directional etching as in the first embodiment described above. By this etching, the film thickness of the photoresist 30 of the first pattern P1 is reduced, and the resist residue 31 of the second pattern P2 is also etched and reduced. By reduction of the resist residue 31, an auxiliary additional portion 21 of the patterning layer 20 patterned on the basis of the resist residue 31 can be prevented from affecting electrical characteristics of the patterning layer 20 patterned on the basis of the first pattern P1.

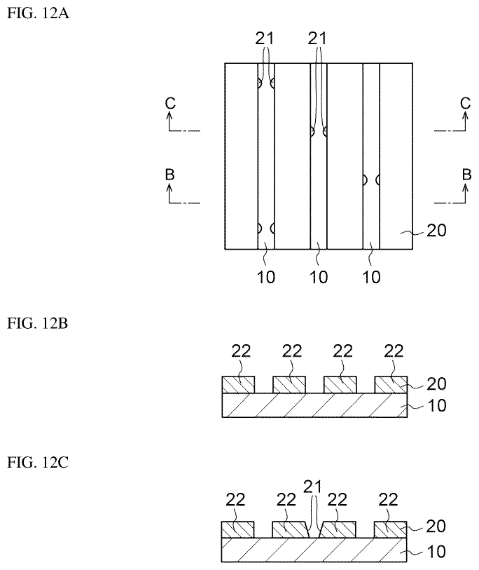

When the photoresist 30 is cleaned and removed from the state of FIGS. 11A to 11C as in the first embodiment described above, the semiconductor substrate becomes the state of FIGS. 12A to 12C. As a result, the semiconductor device manufacturing process for patterning the patterning layer 20 in the present embodiment is completed. Then, this semiconductor substrate shifts to a next manufacturing process.

As described above, according to the semiconductor device manufacturing method according to the present embodiment, as in the first embodiment described above, the photoresist 30 is exposed, developed, and dried using the mask 40 having a pattern in which the second pattern P2 is supplementarily added to the first pattern P1. Therefore, in the development step and the drying step, the resist residue 31 corresponding to the second pattern P2 has a structure supporting the remaining resist 32 corresponding to the first pattern P1, and collapse of the remaining resist 32 corresponding to the first pattern P1 can be avoided.

In addition, since the auxiliary lines L2 of the second pattern P2 are discontinuously dispersed between the first patterns P1, the remaining resist 32 of the photoresist 30 corresponding to the first pattern P1 can be supported in a well-balanced manner, and collapse thereof can be avoided. In addition, the number of the plurality of auxiliary lines L2 in the second pattern P2 can be reduced, and the number of the resist residues 31 to be formed can also be reduced.

### Third Embodiment

In the exposure mask 40 according to the first and second embodiments described above, the plurality of auxiliary lines L2 in the second pattern P2 are arranged so as to connect the parallel mask lines L1 of the first pattern P1 to each other, but the arrangement of the plurality of auxiliary lines L2 is not necessarily limited to the arrangement in which the plurality of auxiliary lines L2 are arranged so as to connect the parallel mask lines LI to each other. In the following third embodiment, an example will be described in which the plurality of auxiliary lines L2 in the second pattern P2 are added to the first pattern P1 so as to protrude from a longitudinal direction of an exposure line of the first pattern P1. Note that, in the description of the third embodiment, portions different from those of the first embodiment described above will be mainly described.

A semiconductor device manufacturing process according to the third embodiment is the same as that of the first embodiment described above up to FIGS. 1A and 1B. That is, the process is similar to that in the first embodiment described above until the photoresist 30 is formed on the patterning layer 20 and prebaked by heating.

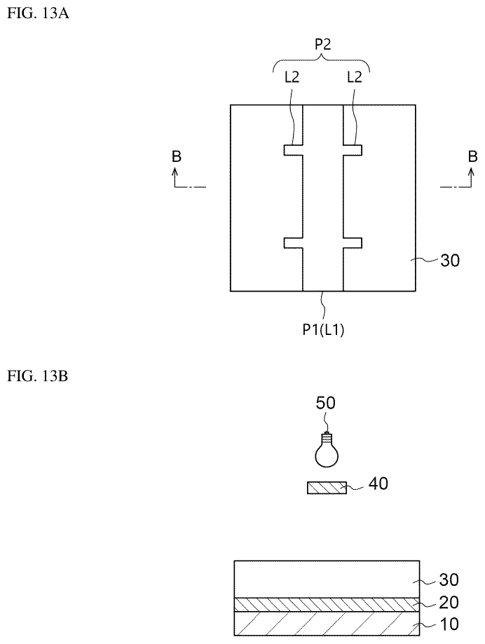

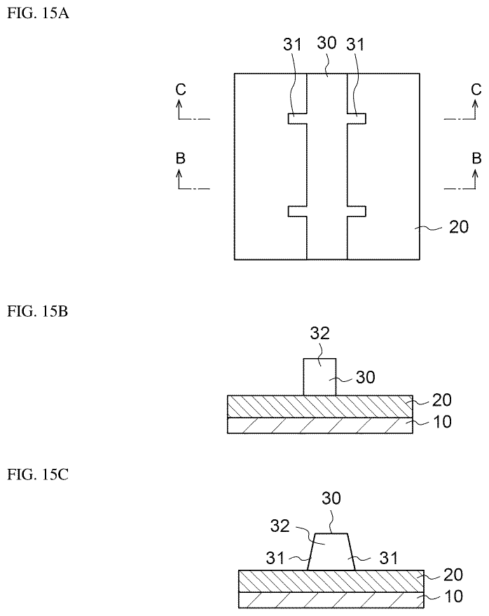

FIGS. 13A to 17A are plan views for explaining the semiconductor device manufacturing process according to the present embodiment, following FIGS. 1A and 1B, and are views corresponding to FIGS. 2A to 6A in the first embodiment described above, respectively. FIGS. 13B to 17B are cross-sectional views of FIGS. 13A to 17A taken along line B-B, respectively. FIGS. 15C to 17C are cross-sectional views of FIGS. 15A to 17A taken along line C-C, respectively.

As illustrated in FIGS. 13A and 13B, the photoresist 30 is exposed using the exposure mask 40 as in the first embodiment described above. Note that a pattern of the exposure mask 40 according to the present embodiment is different from the pattern of the exposure mask 40 of the first embodiment described above. That is, the first pattern P1 is different from the first pattern P1 of the first embodiment, and a pattern of the second pattern P2 supplementarily added to the first pattern P1 is also different from the second pattern P2 of the first embodiment.

Specifically, the first pattern P1 is constituted by one mask line L1. Note that, in the present embodiment, the description will be given focusing only on the one mask line L1, and another exposure line such as another wiring is present in the actual mask 40. That is, FIGS. 13A and 13B are only partial examples.

The plurality of auxiliary lines L2 in the second pattern P2 are supplementarily added to the one mask line L1. In the present embodiment, the plurality of auxiliary lines L2 are added to the first pattern P1 as the second pattern P2 so as to protrude from a longitudinal direction of the one mask line L1. The one mask line L1 is a portion corresponding to the remaining resist 32 in which the photoresist 30 remains after the photoresist 30 is developed. That is, the plurality of auxiliary lines L2 in the second pattern P2 are supplementarily added so as to protrude in a width direction from a longitudinal direction of the remaining resist 32. As a result, the resist residue 31 formed on the basis of the auxiliary line L2 effectively suppresses collapse of the remaining resist 32.

In addition, in the present embodiment, the plurality of auxiliary lines L2 in the second pattern P2 are added to the first pattern P1 so as to be paired with each other with a longitudinal direction of the one mask line L1, that is, a longitudinal direction of the remaining resist 32 as a center. The plurality of auxiliary lines L2 in the second pattern P2 are supplementarily added at predetermined intervals in the longitudinal direction of the one mask line L1 in the first pattern P1, but the interval at which the auxiliary lines L2 are added is arbitrary.

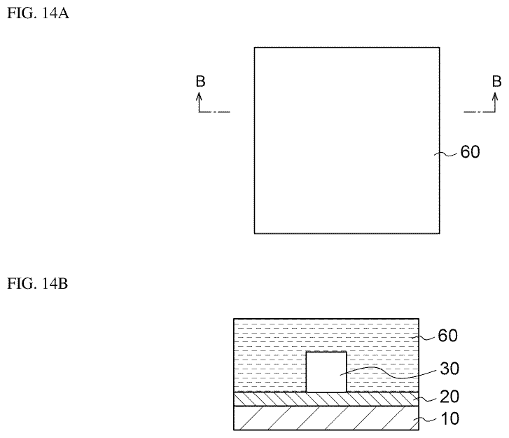

Next, as illustrated in FIGS. 14A and 14B, the exposed photoresist 30 is developed as in the first embodiment described above. This development step is the same as that in the first embodiment described above.

Next, as illustrated in FIGS. 15A and 15C, the developed photoresist 30 is dried as in the first embodiment described above. Through the development step and the drying step, the resist residue 31 corresponding to the second pattern P2 is formed in the photoresist 30. The fact that the resist residue 31 is formed is similar to the first embodiment described above, but since the patterns of the first pattern P1 and the second pattern P2 are different from those of the first embodiment, a position where the resist residue 31 is formed is also different from that of the first embodiment.

As can be seen from the example illustrated in FIG. 15C, in the present embodiment, the resist residues 31 corresponding to the second pattern P2 are formed on both sides of the remaining resist 32 corresponding to the one mask line L1. Therefore, the resist residues 31 support the remaining resist 32 of the photoresist 30 formed corresponding to the first pattern P1 such that the remaining resist 32 does not collapse in either of left and right directions.

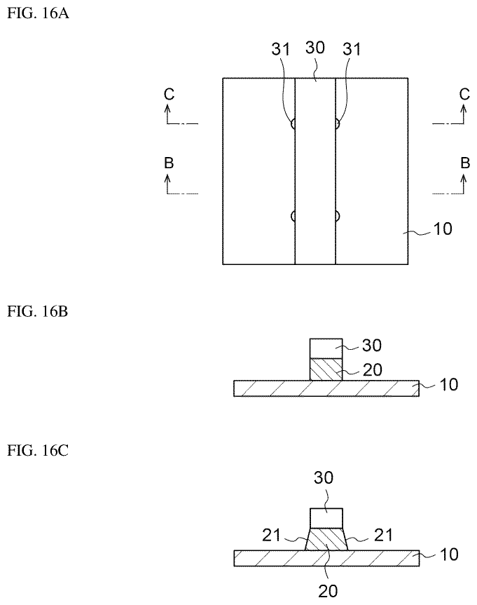

When the patterning layer 20 is etched in the state of FIGS. 15A to 15C, the semiconductor device becomes the state of FIGS. 16A to 16C. In particular, in the present embodiment, the patterning layer 20 is etched by directional etching as in the first embodiment described above. By this etching, the film thickness of the photoresist 30 of the first pattern P1 is reduced, and the resist residue 31 of the second pattern P2 is also etched and reduced. By reduction of the resist residue 31, the auxiliary additional portion 21 of the patterning layer 20 patterned on the basis of the resist residue 31 is also reduced. Therefore, electrical characteristics of the patterning layer 20 patterned based on the first pattern P1 can be prevented from being affected. That is, in the present embodiment, one remaining resist 32 is formed corresponding to one mask line L1 of the first pattern P1. If the auxiliary additional portion 21 formed in the middle of the remaining resist 32 is large, there is a possibility that the electrical characteristics are affected, but it is considered that such a possibility is substantially eliminated by reducing the auxiliary additional portion 21 as in the present embodiment.

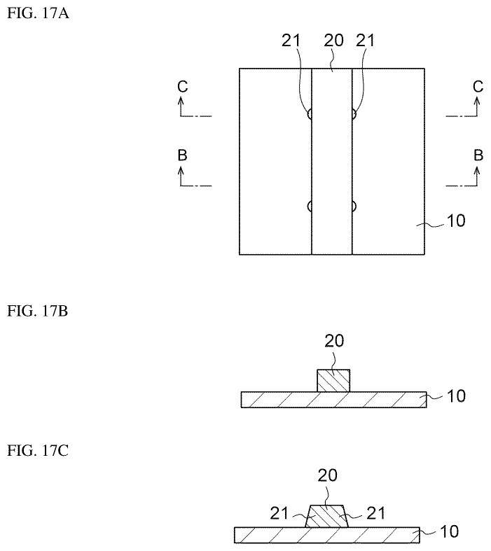

When the photoresist 30 is cleaned and removed from the state of FIGS. 16A to 16C as in the first embodiment described above, the semiconductor substrate becomes the state of FIGS. 17A to 17C. As a result, the semiconductor device manufacturing process for patterning the patterning layer 20 in the present embodiment is completed. Then, this semiconductor substrate shifts to a next manufacturing process.

As described above, according to the semiconductor device manufacturing method according to the present embodiment, as in the first embodiment described above, the photoresist 30 is exposed, developed, and dried using the mask 40 having a pattern in which the second pattern P2 is supplementarily added to the first pattern P1. Therefore, in the development step and the drying step, the resist residue 31 corresponding to the second pattern P2 has a structure supporting the remaining resist 32 corresponding to the first pattern P1, and collapse of the remaining resist 32 corresponding to the first pattern P1 can be avoided.

As described above, also by supplementarily adding the plurality of auxiliary lines L2 to one mask line L1 of the first pattern P1 such that the plurality of auxiliary lines L2 are not connected to a mask line L1 of another first pattern P1, it is possible to suppress collapse of the remaining resist 32 remaining after the photoresist 30 is developed on the basis of the first pattern P1.

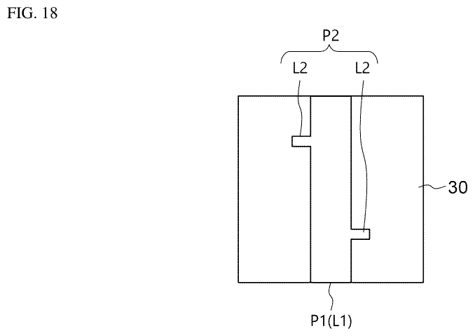

FIG. 18 is a view illustrating a part of a semiconductor device manufacturing process illustrating a modification of the third embodiment, and is a view corresponding to FIG. 13A described above. In the modification of FIG. 18, the auxiliary lines L2 of the second pattern P2 are added to the first pattern P1 so as to be arranged on one side with a longitudinal direction of one mask line L1 of the first pattern P1 as a center. That is, in the description of the third embodiment described above, the auxiliary lines L2 are added to the left and right sides so as to be paired with each other with a longitudinal direction of one mask line L1 of the first pattern P1 as a center. However, as illustrated in FIG. 18, the auxiliary lines L2 may be added to one side with a longitudinal direction of one mask line L1 as a center, but do not have to be added to the other side.

Note that the pattern of the exposure mask 40 may be a combination of the pattern of FIG. 13A and the pattern of FIG. 18A. That is, the pattern of the mask 40 may be a pattern in which the auxiliary lines L2 arranged so as to be paired with each other with a longitudinal direction of one mask line L1 of the first pattern P1 as a center and the auxiliary lines L2 arranged on one side with a longitudinal direction of one mask line L1 as a center are mixed.

Note that the embodiments described above merely disclose an example, and various modifications and combinations of the embodiments are possible. For example, the manufacturing methods in the manufacturing processes described in the embodiments described above are merely examples, and the semiconductor device manufacturing processes in the embodiments described above can be implemented by another manufacturing method.

1. A semiconductor device manufacturing method comprising:
a step of applying a photoresist onto a first pattern to be a patterning layer formed by patterning;
a step of exposing the photoresist using a mask in which a second pattern is supplementarily added to the first pattern;
a step of developing the exposed photoresist in order to form the second pattern and a resist residue; and
a step of etching the patterning layer using the dried photoresist, wherein
in the etching step, the resist residue of the second pattern is also etched and reduced such that a portion of the patterning layer patterned on a basis of the resist residue of the second pattern does not affect electrical characteristics of the patterning layer patterned on a basis of the first pattern.

2. The semiconductor device manufacturing method according to claim 1, wherein the second pattern is added to the first pattern so as to connect remaining resists where the photoresist remains after the photoresist is developed on a basis of the first pattern to each other.

3. The semiconductor device manufacturing method according to claim 2, wherein in the second pattern, a plurality of auxiliary lines are arranged so as to be continuously arranged in a certain direction and added to the first pattern.

4. The semiconductor device manufacturing method according to claim 2, wherein the second pattern is discontinuously dispersed and added to the first pattern.

5. The semiconductor device manufacturing method according to claim 1, wherein a plurality of auxiliary lines are added to the first pattern as the second pattern so as to protrude in a width direction from a longitudinal direction of a remaining resist where the photoresist remains after the photoresist is developed on a basis of the first pattern.

6. The semiconductor device manufacturing method according to claim 5, wherein in the second pattern, the plurality of auxiliary lines are added to the first pattern so as to be paired with each other with a longitudinal direction of the remaining resist as a center.

7. The semiconductor device manufacturing method according to claim 5, wherein in the second pattern, the plurality of auxiliary lines are added to the first pattern so as to be arranged on one side with a longitudinal direction of the remaining resist as a center.

8. The semiconductor device manufacturing method according to claim 1, wherein in the step of exposing the photoresist, the photoresist is exposed using an exposure light source having a wavelength of 13.5 nm.

9. The semiconductor device manufacturing method according to claim 8, wherein a line width formed in a patterning layer in the first pattern is between one time and two times a wavelength of the exposure light source.

10. The semiconductor device manufacturing method according to claim 9, wherein in the step of exposing the photoresist, the photoresist is exposed using a lens having a numerical aperture of 0.55 or more.

11. The semiconductor device manufacturing method according to claim 1, wherein in the step of etching the patterning layer, the resist residue of the second pattern is also etched by performing directional etching on the patterning layer from a direction intersecting with a longitudinal direction of the second pattern.

12. The semiconductor device manufacturing method according to claim 1, wherein the resist residues remaining after the photoresist is dried are separated from each other while each of the resist residues has a widened skirt portion in contact with the patterning layer.

13. A semiconductor device comprising:
a first member formed in a first pattern which is a design pattern; and
a second member which is added to the first member and is formed continuously with the first member, is formed of a resist residue of a photoresist of a second pattern supplementarily added to the first pattern, is separated from the first members and another second member, and does not affect electrical characteristics of the first member formed in the first pattern.
